(19) United States
(12) Patent Application Publication
(10) Pub. No.: US 2026/0293283 A1
(43) Pub. Date: Sep. 24, 2026

(54) DUAL GATE TRENCH MOSFET WITH SHIELDED GATE ELECTRODE IN STEP TRENCH

(71) Applicant: Nami MOS CO., LTD., New Taipei City (TW)

(72) Inventors: Fu-Yuan HSIEH, New Taipei City (TW); Lin XU, Shanghai (CN)

(73) Assignee: Nami MOS CO., LTD., New Taipei City (TW)

(21) Appl. No.: 19/082,685

(22) Filed: Mar. 18, 2025

(51) Int. Cl. H10D 84/00; H10D 8/00; H10D 30/60; H10D 30/66; H10D 62/10; H10D 62/60; H10D 64/01; H10D 64/23; H10D 64/68

(52) U.S. Cl. CPC H10D 84/143; H10D 8/825; H10D 30/611; H10D 30/662; H10D 30/665; H10D 30/668; H10D 62/102; H10D 62/127; H10D 62/60; H10D 64/025; H10D 64/2527; H10D 64/685; H10D 64/693

(57) ABSTRACT

A dual gate trench power device comprises a first MOSFET integrated with a super barrier rectifier (SBR) or with a second MOSFET in each unit cell having a shielded gate electrode in a one-step gate trench. The one-step gate trench comprising a top gate trench with a narrower trench width than a bottom gate trench for the unit cell pitch shrinkage. Specific on-resistance and reverse recovery time are thus reduced with the improved structures.

### FIELD OF THE INVENTION

This invention generally relates to a unit cell structure of a power semiconductor device having two types of gate trenches with a shielded gate electrode in a one-step gate trench, and more particularly, to integrate a first trench Metal Oxide Semiconductor Field Effect Transistor (MOSFET) with a Super Barrier Rectifier (SBR) or with a second MOSFET forming a hybrid channel MOSFET (HCMOSFET) to achieve a lower on-resistance, and a less switching loss. The novel device cell pitch can be shrunk because the one-step gate trench structure has a narrower trench width at the top portion than the bottom portion.

### BACKGROUND OF THE INVENTION

Compared with conventional trench MOSFETs, Shielded Gate Trench (SGT) MOSFETs are more attractive due to a lower specific drain-source resistance (Rsp) and an improved overall efficiency in most applications without compromising ruggedness of the device as a result of the oxide charge balance (OCB) regions formed between two adjacent deep trenches. However, wafer warpage becomes a serious issue for the SGT MOSFETs with a stripe shaped deep trench when wafer diameter increases or breakdown voltage increases. The main reasons for the rise in the wafer warpage are the increasing depth of deep trenches and the increasing thickness of field oxide, as the breakdown voltage and wafer diameter increase. When the wafer warpage exceeds a critical value, errors in vacuum absorption or wafer transportation may occur in some equipment, and the wafers cannot be processed anymore. Moreover, the increasing field oxide thickness occupies a large space in the unit cell region, resulting in high specific on-resistance.

Moreover, a parasitic PIN body diode of the SGT MOSFET deteriorates reverse recovery characteristics. As a result, various irradiations and Platinum diffusion techniques are normally used to reduce reverse recovery time Trr of the parasitic PIN diode. However, high leakage current between drain and source, and negative temperature coefficient in Breakdown voltage issues are observed at high temperature applications.

Therefore, there is still a need in the art of the semiconductor power device, particularly for the SGT MOSFET design, to provide a novel cell structure and device configuration that would resolve design limitations and improve device performance.

### SUMMARY OF THE INVENTION

The present invention provides a trench MOSFET having various shielded gate shapes integrated with a super barrier rectifier (SBR) as a MOS-channel diode, having a shielded gate electrode in a one-step gate trench to inactivate a parasitic diode in the trench MOSFET from turning-on for the switching loss reduction. The integrated SBR creates a low potential barrier for the majority carriers in the MOS channel, which is adjustable by gate oxide thickness, P body doping concentration and channel length. The SBR has a lower forward voltage Vf and a lower reverse leakage current Ir than the Schottky Barrier diode (SBD). Moreover, the SBR has a better and reliable performance at elevated temperature than the SBD.

According to another aspect, the invention features a power device further comprising a second MOSFET having a shielded gate electrode in a bottom gate trench of the one-step gate trench to form a hybrid-channel MOSFET (HCMOSFET) with the first MOSFET in the unit cell of the power device for the specific on-resistance reduction, wherein the HCMOSFET has two different threshold voltages formed by an additional short channel implantation in a channel region of the second MOSFET to improve the positive temperature coefficient for reliability assurance operated at high temperatures.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIG. 1A is a top view of a preferred embodiment for a trench semiconductor power device with hexagonal closed cells layout comprising two types of gate trenches according to the present invention.

FIG. 1B is a cross-sectional view showing a preferred A1-A1’ cross section of FIG. 1A comprising two types of gate trenches with a single epitaxial layer according to the present invention, wherein the second type gate trench has a one-step gate trench structure.

FIG. 1C is a top view of another preferred embodiment for a trench semiconductor power device with square closed cells layout according to the present invention.

FIG. 1D is a top view of another preferred embodiment for a trench semiconductor power device with stripe cells layout according to the present invention.

FIG. 1E is a cross-sectional view showing another preferred A1-A1’ cross section of FIG. 1A with two stepped epitaxial layers according to the present invention, wherein the doping concentration variations of the N type epitaxial layer as grown are depicted along the vertical direction.

FIG. 1F is a cross-sectional view showing another preferred A1-A1’ cross section of FIG. 1A with multiple stepped epitaxial (MSE) layers according to the present invention, wherein the doping concentration variations of the N type epitaxial layer as grown are depicted along the vertical direction.

FIG. 1G is a cross-sectional view showing another preferred A1-A1’ cross section of FIG. 1A with MSE layers according to the present invention, wherein the doping concentration variations of the N type epitaxial layer as grown are depicted along the vertical direction.

FIG. 2A is a top view of another preferred embodiment for a trench semiconductor power device comprising a trench MOSFET integrated with a super barrier rectifier (SBR) as a MOS-channel diode with hexagonal closed cells layout according to the present invention.

FIG. 2B is a cross-sectional view showing a preferred A2-A2’ cross section of FIG. 2A comprising a trench MOSFET integrated with a SBR as a MOS-channel diode with a single epitaxial layer according to the present invention.

FIG. 2C is a top view of another preferred embodiment for a trench semiconductor power device comprising a trench MOSFET integrated with a SBR as a MOS-channel diode with square closed cells layout according to the present invention.

FIG. 2D is a top view of another preferred embodiment for a trench semiconductor power device comprising a trench MOSFET integrated with a SBR as a MOS-channel diode with stripe cells layout according to the present invention.

FIG. 2E is a cross-sectional view showing another preferred A2-A2’ cross section of FIG. 2A with two stepped epitaxial layers according to the present invention, wherein the doping concentration variations of the N type epitaxial layer as grown are depicted along the vertical direction.

FIG. 2F is a cross-sectional view showing another preferred A2-A2’ cross section of FIG. 2A comprising electric field reducing regions surrounding bottom regions of the second type gate trenches with MSE layers according to the present invention, wherein the doping concentration variations of the N type epitaxial layer as grown are depicted along the vertical direction.

FIG. 2G is a cross-sectional view showing another preferred A2-A2’ cross section of FIG. 2A with MSE layers according to the present invention, wherein the doping concentration variations of the N type epitaxial layer as grown are depicted along the vertical direction.

FIG. 2H is a cross-sectional view showing another preferred A2-A2’ cross section of FIG. 2A comprising electric field reducing regions surrounding bottom regions of the second type gate trenches with MSE layers according to the present invention, wherein the doping concentration variations of the N type epitaxial layer as grown are depicted along the vertical direction.

FIG. 3 is a cross-sectional view showing another preferred A2-A2’ cross section of FIG. 2A comprising a second shielded gate electrode in the first type gate trench with MSE layers according to the present invention, wherein the doping concentration variations of the N type epitaxial layer as grown are depicted along the vertical direction.

FIG. 4A is a top view of another preferred embodiment for a trench semiconductor power device comprising a second MOSFET integrated with a first MOSFET to form a hybrid-channel MOSFET (HCMOSFET) with stripe cells layout according to the present invention.

FIG. 4B is a cross-sectional view showing a preferred A3-A3’ cross section of FIG. 4A comprising a second MOSFET integrated with a first MOSFET to form a HCMOSFET according to the present invention.

FIG. 4C is a cross-sectional view showing another preferred A3-A3’ cross section of FIG. 4A with two stepped epitaxial layers according to the present invention, wherein the doping concentration variations of the N type epitaxial layer as grown are depicted along the vertical direction.

FIG. 4D is a cross-sectional view showing another preferred A3-A3’ cross section of FIG. 4A with MSE layers according to the present invention, wherein the doping concentration variations of the N type epitaxial layer as grown are depicted along the vertical direction.

FIG. 4E is a cross-sectional view showing another preferred A3-A3’ cross section of FIG. 4A with MSE layers according to the present invention, wherein the doping concentration variations of the N type epitaxial layer as grown are depicted along the vertical direction.

FIG. 5 is a cross-sectional view showing another preferred A3-A3’ cross section of FIG. 4A comprising a second MOSFET (MOS2) integrated with a first MOSFET (MOS1) to form a HCMOSFET with two different threshold voltages according to the present invention.

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

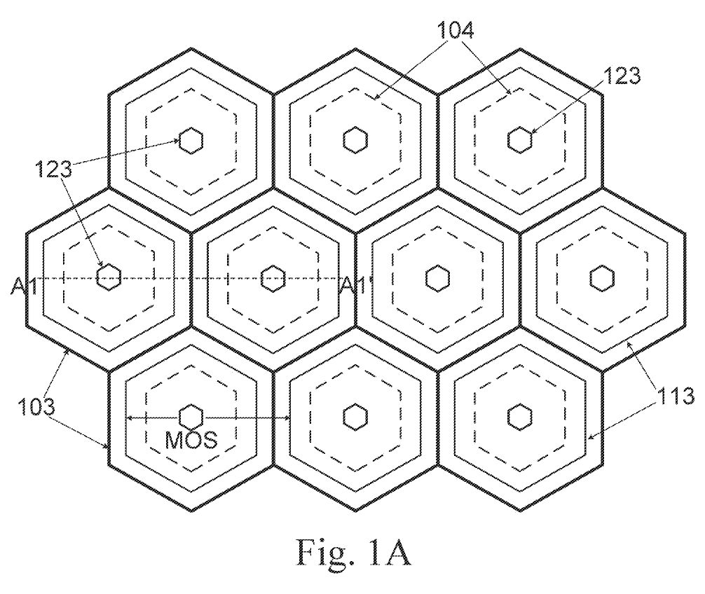

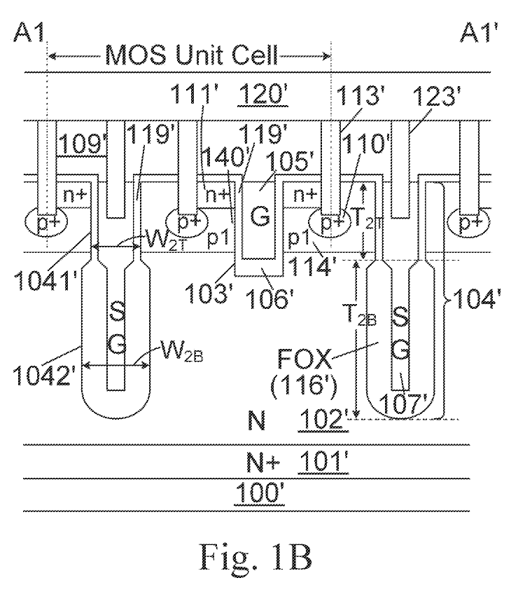

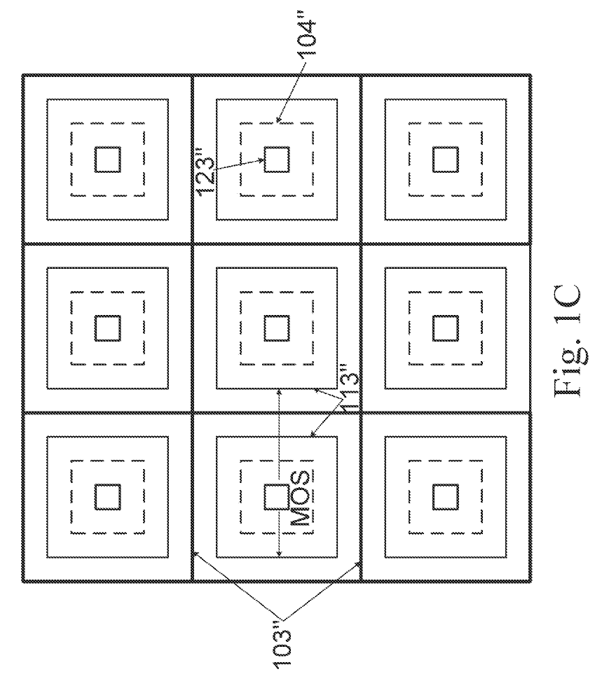

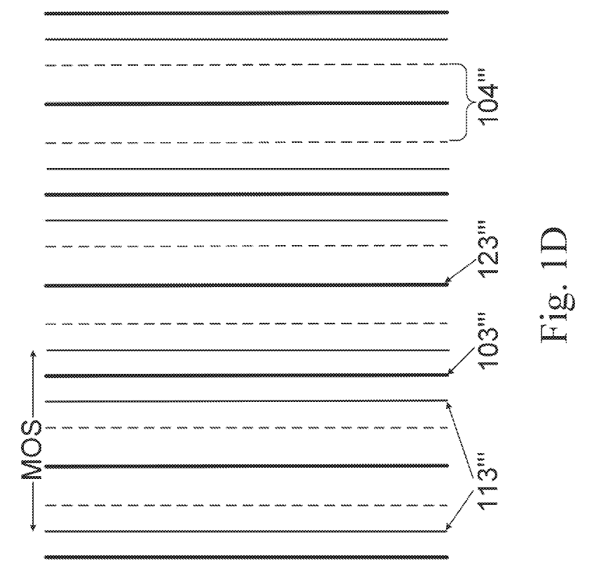

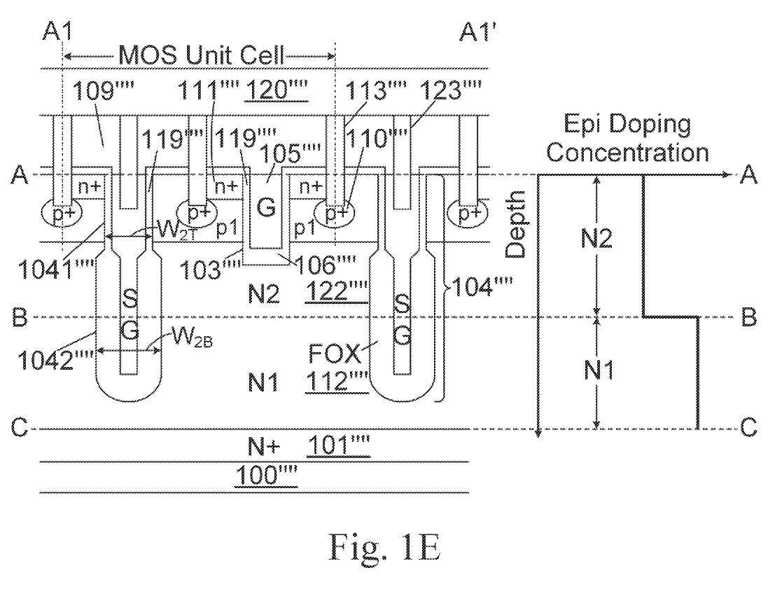

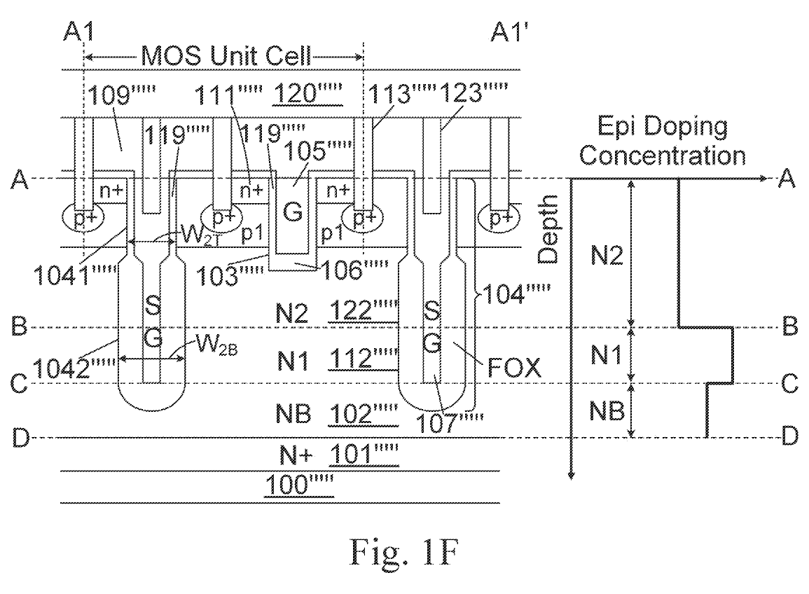

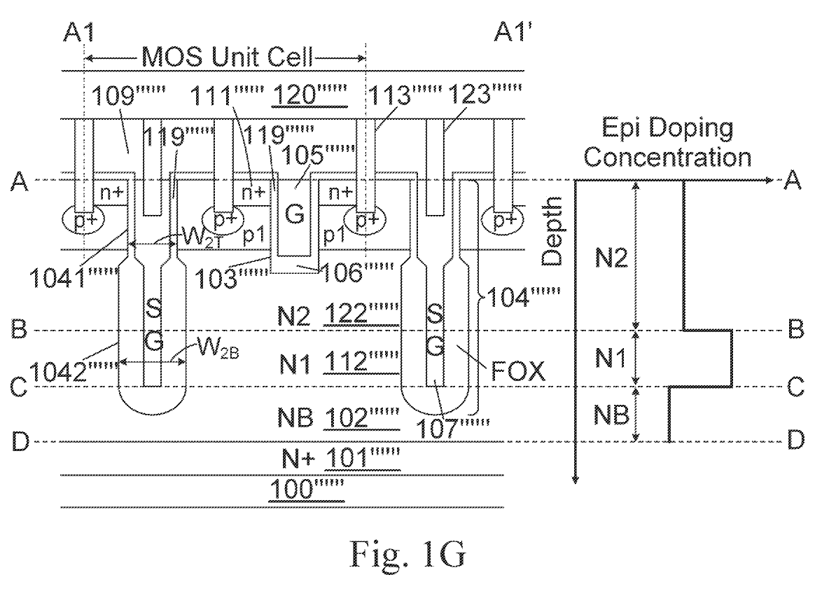

Please refer to FIG. 1A for a top view of a preferred embodiment for a trench semiconductor power device comprising a plurality of unit cells with each unit cell comprising two types of gate trenches. Each of the unit cells has a first type gate trench 103 with a hexagonal shape surrounds a second type gate trench 104. The second type gate trench 104 has a hexagonal shape surrounding a shielded gate contact trench 123. Moreover, a source contact trench 113 with a hexagonal shape is formed between the first type gate trench 103 and the second type gate trench 104, and a MOS unit cell region is formed between the source contact trenches 113 of the two adjacent unit cells.

Please refer to FIG. 1B for a cross-sectional view showing a preferred embodiment along A1-A1’ line of FIG. 1A with a single epitaxial layer according to the present invention. The preferred embodiment comprises an N-channel SGT MOSFET formed in an N type epitaxial layer 102’ onto an N+ substrate 101’ coated with a back metal 100’ on rear side as a drain metal, wherein the power device in the present invention comprises two types of gate trenches in each MOS unit cell. Inside the N type epitaxial layer 102’, a plurality of first type gate trenches 103’ and second type gate trenches 104’ are formed vertically downward from a top surface of the N type epitaxial layer 102’ and not reaching the common interface between the N type epitaxial layer 102’ and the N+ substrate 101’, wherein the second type gate trench 104’ has a trench depth deeper than that of the first type gate trench 103’. Inside each of the first type gate trenches 103’, a gate electrode 105’ (G, as illustrated) is disposed in an upper portion and surrounded with a bottom oxide 106’ on a bottom of the first type gate trenches 103’, and with a first gate oxide (GOX1) 119’ on sidewalls of the first type gate trenches 103’, wherein the bottom oxide 106’ has a thickness same as or greater than the GOX1 119’. Each of the second type gate trenches 104’ has a one-step gate trench structure comprising a second top gate trench 1041’ with a trench depth T2T and a second bottom gate trench 1042’ with a trench depth T2B, wherein the second top gate trench 1041’ is above the second bottom gate trench 1042’ with a trench width W2T less than a trench width W2B of the second bottom gate trench 1042’. A shielded gate electrode (SG, as illustrated) 107’ is formed in each of the second type gate trenches 104’ and surrounded with a first insulating film (FOX, as illustrated) 116’ on a bottom region and along sidewalls of the second bottom gate trench 1042’ and with the GOX1 119’ along sidewalls of the second top gate trench 1041’, wherein the FOX 116’ has a thickness greater than that of the GOX1 119’. The FOX 116’ is formed by Local Oxidation of Silicon (LOCOS). During the LOCOS, sidewalls of said second top gate trench are padded with either a silicon nitride layer or two-layer stack of silicon nitride and silicon oxide to prevent the sidewalls from oxidation. Between the first type gate trench 103’ and the second type gate trench 104’, a first p (p1, as illustrated) body region 114’ with an n+ source region 111’ thereon is extending at a top surface of the N type epitaxial layer 102’ and surrounding the gate electrode 105’ padded by the GOX1 119’, wherein a p+ body contact region 110’ is formed below the n+ source regions 111’ in the p1 body regions 114’ to reduce the body contact resistance. A first channel region 140’ of the MOSFET is formed in the p1 body region 114’ along sidewalls of the first type gate trench 103’ connecting to the first source region 111’. An interlayer dielectric film 109’ is stacked on the epitaxial layer 102’, and a source metal 120’ is formed onto the interlayer dielectric film 109’. The p1 regions 114’ and the first n+ source regions 111’, and the SG 107’ are shorted to the source metal 120’ through a plurality of source contact trenches 113’ and shielded gate contact trenches 123’, respectively, wherein the source contact trenches 113’ and shielded gate contact trenches 123’ are filled with contact metal plugs and metal barriers, and the source contact trenches 113’ are surrounded by the p+ heavily doped regions 110’ around bottoms underneath the first n+ source regions 111’.

Please refer to FIG. 1C for a top view of another preferred embodiment for a trench semiconductor power device comprising a plurality of unit cells with each unit cell comprises two types of gate trenches. The power device has a similar structure to FIG. 1A, except that the unit cell, the first and second type gate trenches 103’’ and 104’’, the source contact trenches 113’’ and the shielded gate contact trenches 123’’ in the present invention all have a square shape.

Please refer to FIG. 1D for a top view of another preferred embodiment for a trench semiconductor power device comprising a plurality of unit cells with each unit cell comprises two types of gate trenches. The power device has a similar structure to FIG. 1A, except that the unit cell, the first and second type gate trenches 103’’’ and 104’’’, the source contact trenches 113’’’ and the shielded gate contact trenches 123’’’ in the present invention all have a stripe shape.

Please refer to FIG. 1E for a cross-sectional view showing another preferred embodiment along A1-A1’ line of FIG. 1A with a new and improved device structure having two stepped epitaxial layers wherein the doping concentration variations are depicted along the vertical direction according to the present invention. The N-channel trenched semiconductor power device has a similar structure to FIG. 1B, except that, the N type epitaxial layer in the present invention comprises two stepped epitaxial layers of different doping concentration including a bottom 1^{st} epitaxial layer (N1, as illustrated between B-B and C-C lines) 112’’’’ a with doping concentration D1 and a top 2^{nd} epitaxial layer (N2, as illustrated between A-A and B-B lines) 122’’’’ with a doping concentration D2, wherein D2< D1, to further reduce the specific on-resistance.

Please refer to FIG. 1F for a cross-sectional view showing another preferred embodiment along A1-A1’ line of FIG. 1A with a new and improved device structure having three stepped epitaxial layers wherein the doping concentration variations are depicted along the vertical direction according to the present invention. The N-channel trenched semiconductor power device has a similar structure to FIG. 1E, except that, the present invention further comprises a buffer epitaxial layer (NB, as illustrated) 102’’’’’ between a bottom of the shielded gate electrode (SG, as illustrated) 107’’’’’ and the N+ substrate 101’’’’’ with a doping concentration DB, wherein D2<DB<D1.

Please refer to FIG. 1G for a cross-sectional view showing another preferred embodiment along A1-A1’ line of FIG. 1A with a new and improved device structure having three stepped epitaxial layers wherein the doping concentration variations are depicted along the vertical direction according to the present invention. The N-channel trenched semiconductor power device has a similar structure to FIG. 1E, except that, the N type epitaxial layer in the present invention further comprises a buffer epitaxial layer (NB, as illustrated) 102’’’’’’ between a bottom of the shielded gate electrode (SG, as illustrated) 107’’’’’’ and the N+ substrate 101’’’’’’ with a doping concentration DB, wherein DB<D2< D1.

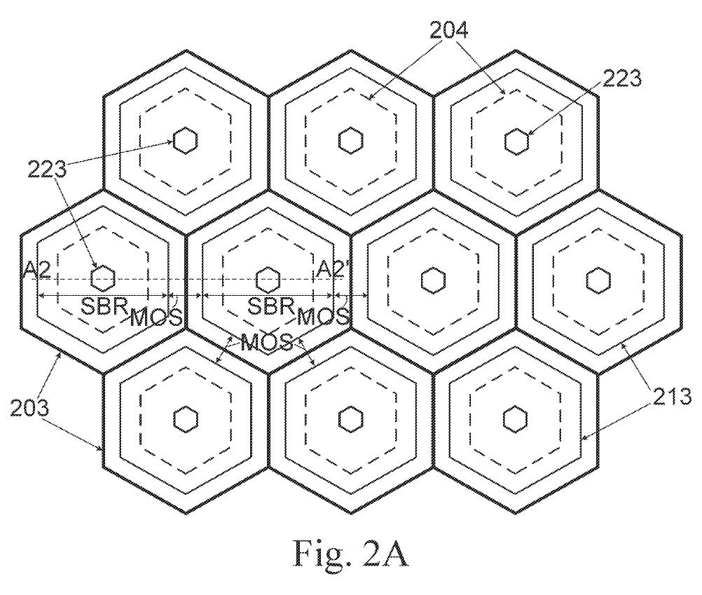

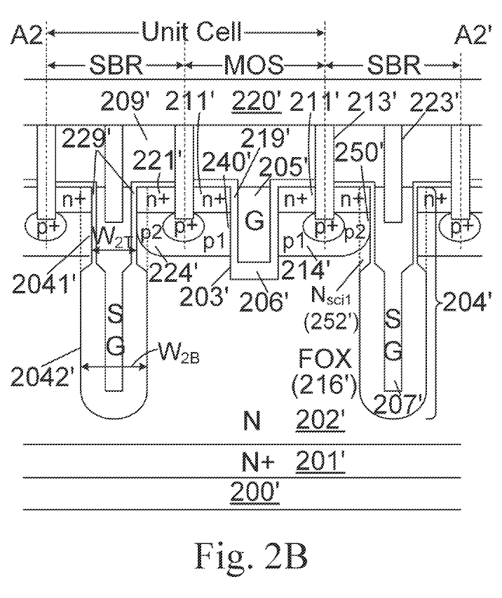

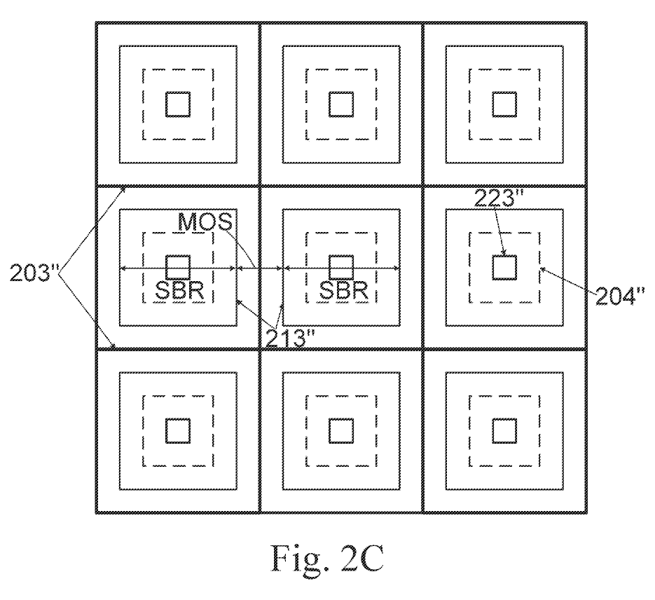

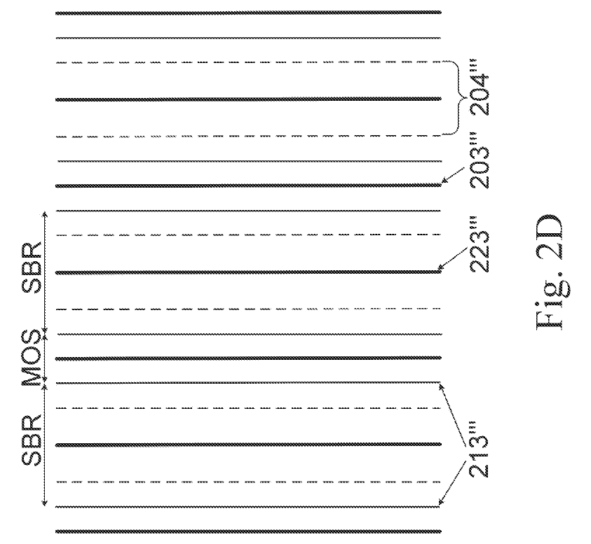

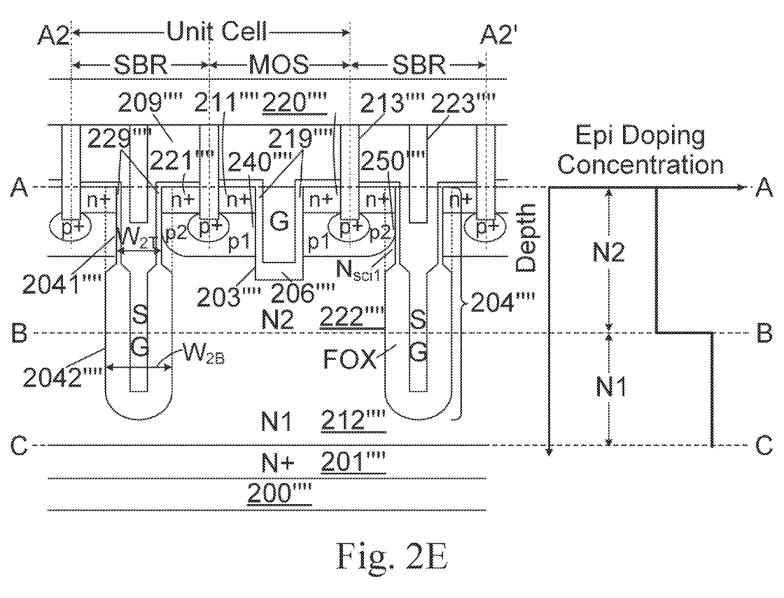

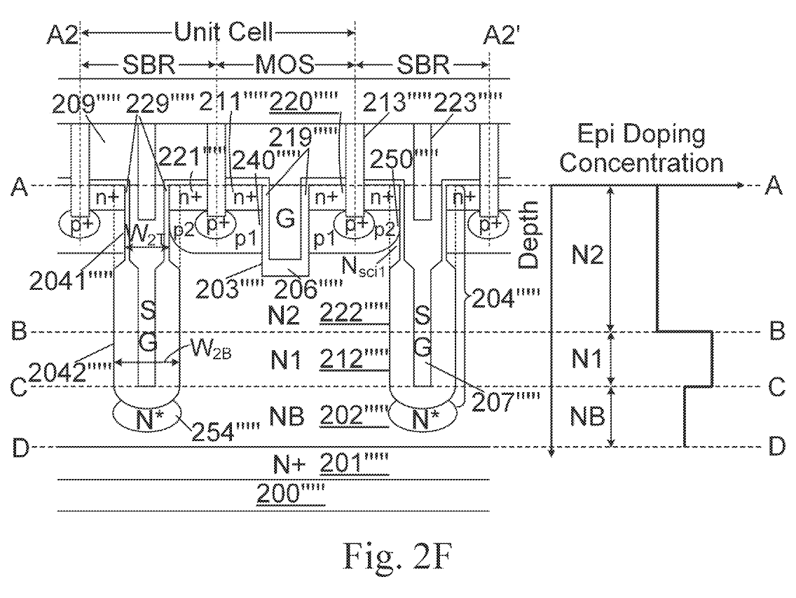

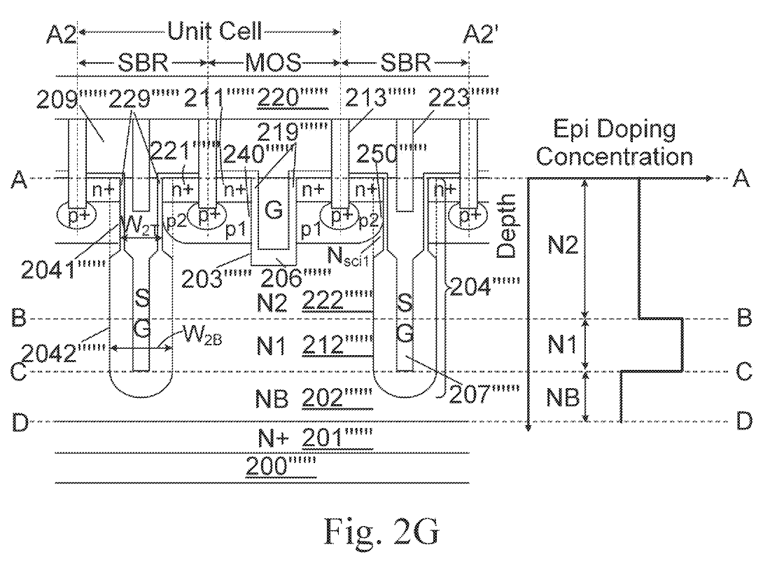

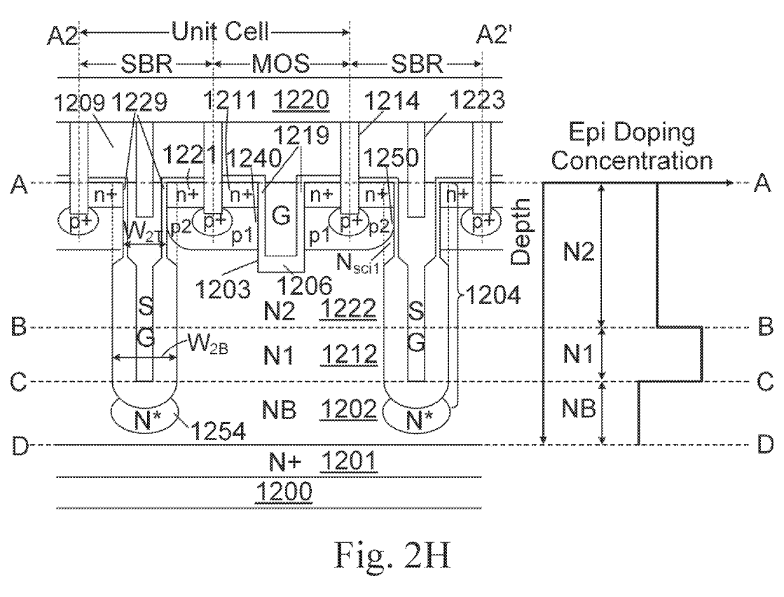

Please refer to FIG. 2A for a top view of another preferred embodiment for a trench semiconductor power device comprising a plurality of unit cells with each unit cell comprises two types of gate trenches. The power device has a similar structure to FIG. 1A, except that each unit cell in the present invention further comprises a super barrier rectifier (SBR, as illustrated) integrated with the MOSFET (MOS, as illustrated), and the SBR comprises a shielded gate contact 223 and a second type gate trench 204 between the two adjacent source contact trenches 213 in each unit cell, while the MOS comprises a first type gate trench 203 between the two source contact trenches 213 of the two adjacent unit cells. The MOS surrounds the SBR.

Please refer to FIG. 2B for a cross-sectional view showing a preferred embodiment along A2-A2’ line of FIG. 2A with a single epitaxial layer according to the present invention. The N-channel trenched semiconductor power device has a similar structure to FIG. 1B, except for the different gate trench structure in the second type gate trench 204’ to form a super barrier rectifier (SBR, as illustrated) region. According to this invention, a SBR region is integrated with the first MOSFET (MOS, as illustrated) in each unit cell. The present invention in FIG. 2B further comprises a second p body (p2, as illustrated) region 224’ of a second conductivity type having a second n+ source region 221’ of a first conductivity type thereon, wherein the p2 body region 224’ along sidewalls of the second top gate trench 2041’ has a doping concentration lower than that of the p1 body region 214’. The second type gate trench 204’ penetrating through said p2 region 224’ and the second n+ source region 221’ and stopping into an N type epitaxial layer 202’. A second channel region 250’ of the SBR region is thus formed in the p2 body region 224’ along sidewalls of the second top gate trench 2041’ connecting to the second n+ source region 221’, and the second channel region 250’ has a channel length shorter than that of the first channel region 240’. Moreover, an N type first short channel implant (Nsci1, as illustrated) region 252’ is formed surrounding the second channel region 250’ by Arsenic or Phosphorus angle implantation along sidewalls of the top gate trench 2041’ of the second type gate trench 204’, and having a doping concentration higher than that of the N type epitaxial layer 202’.

Please refer to FIG. 2C for a top view of another preferred embodiment for a trench semiconductor power device comprising a plurality of unit cells with each unit cell comprises two types of gate trenches. The power device has a similar structure to FIG. 2A, except that the unit cell, the first and second type gate trenches 203’’ and 204’’, the source contact trenches 213’’ and the shielded gate contact trenches 223’’ in the present invention all have a square shape.

Please refer to FIG. 2D for a top view of another preferred embodiment for a trench semiconductor power device comprising a plurality of unit cells with each unit cell comprises two types of gate trenches. The power device has a similar structure to FIG. 2A, except that the unit cell, the first and second type gate trenches 203’’’ and 204’’’, the source contact trenches 213’’’ and the shielded gate contact trenches 223’’’ in the present invention all have a stripe shape.

Please refer to FIG. 2E for a cross-sectional view showing another preferred embodiment along A2-A2’ line of FIG. 2A with a new and improved device structure having two stepped epitaxial layers wherein the doping concentration variations are depicted along the vertical direction according to the present invention. The N-channel trenched semiconductor power device has a similar structure to FIG. 2B, except that, the N type epitaxial layer in the present invention comprises two stepped epitaxial layers of different doping concentration including a bottom 1^{st} epitaxial layer (N1, as illustrated between B-B and C-C lines) 212’’’’ a with doping concentration D1 and a top 2^{nd} epitaxial layer (N2, as illustrated between A-A and B-B lines) 222’’’’ with a doping concentration D2, wherein D2< D1, to further reduce the specific on-resistance.

Please refer to FIG. 2F for a cross-sectional view showing another preferred embodiment along A2-A2’ line of FIG. 2A with a new and improved device structure having three stepped epitaxial layers wherein the doping concentration variations are depicted along the vertical direction according to the present invention. The N-channel trenched semiconductor power device has a similar structure to FIG. 2E, except that, the N type epitaxial layer in the present invention further comprises a buffer epitaxial layer (NB, as illustrated) 202’’’’’ between a bottom of the shielded gate electrode (SG, as illustrated) 207’’’’’ and the N+ substrate 201’’’’’ with a doping concentration DB, wherein D2<DB<D1. Moreover, an N type electric field reducing (N*, as illustrated) region 254’’’’’ is formed surrounding a bottom region of the second type gate trench 204’’’’’ with a doping concentration lower than a doping concentration DB of the NB region 202’’’’’.

Please refer to FIG. 2G for a cross-sectional view showing another preferred embodiment along A2-A2’ line of FIG. 2A with a new and improved device structure having three stepped epitaxial layers wherein the doping concentration variations are depicted along the vertical direction according to the present invention. The N-channel trenched semiconductor power device has a similar structure to FIG. 2E, except that, the N type epitaxial layer in the present invention further comprises a buffer epitaxial layer (NB, as illustrated) 202’’’’’’ between a bottom of the shielded gate electrode (SG, as illustrated) 207’’’’’’ and the N+ substrate 201’’’’’’ with a doping concentration DB, wherein DB<D2< D1.

Please refer to FIG. 2H for a cross-sectional view showing another preferred embodiment along A2-A2’ line of FIG. 2A with a new and improved device structure having three stepped epitaxial layers wherein the doping concentration variations are depicted along the vertical direction according to the present invention. The N-channel trenched semiconductor power device has a similar structure to FIG. 2G, except that the present invention further comprises an N type electric field reducing (N*, as illustrated) region 1254 surrounding a bottom region of the second type gate trench 1204 with a doping concentration lower than a doping concentration DB of the NB region 1202.

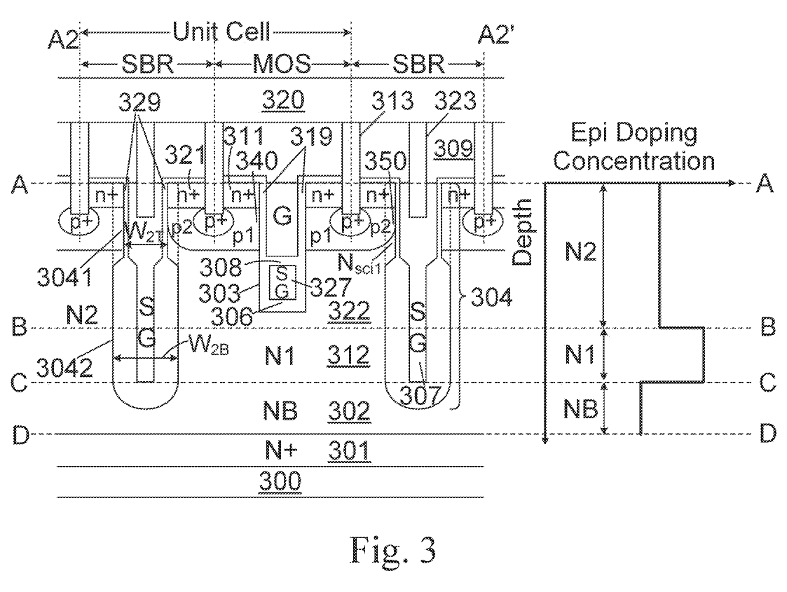

Please refer to FIG. 3 for a cross-sectional view showing another preferred embodiment along A2-A2’ line of FIG. 2A with a new and improved device structure having three stepped epitaxial layers wherein the doping concentration variations are depicted along the vertical direction according to the present invention. The N-channel trenched semiconductor power device has a similar structure to FIG. 2G, except for the different gate trench structure in the first type gate trenches 303. The present invention in FIG. 3B further comprises a second shielded gate electrode (SG, as illustrated) 327 disposed below the first gate electrode (G, as illustrated) 305 in the first type gate trenches 303 and isolated from the first gate electrode 305 with a first inter-polysilicon oxide (IPO1) layer 308.

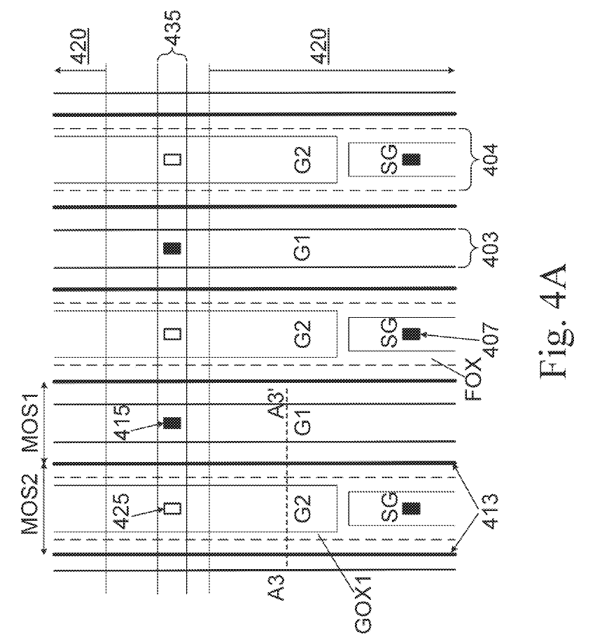

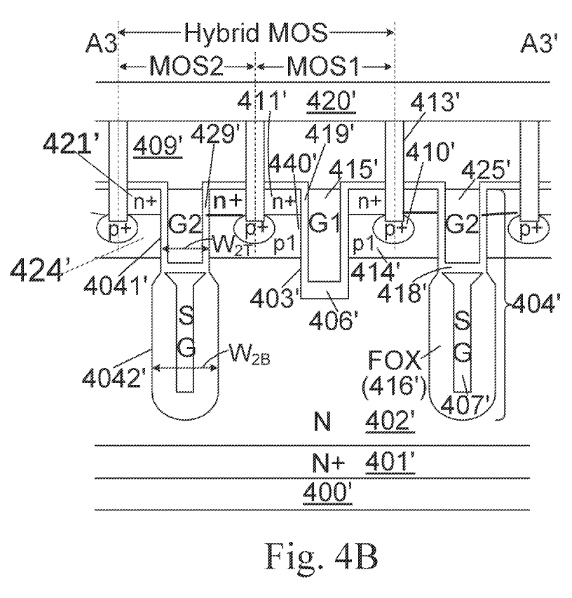

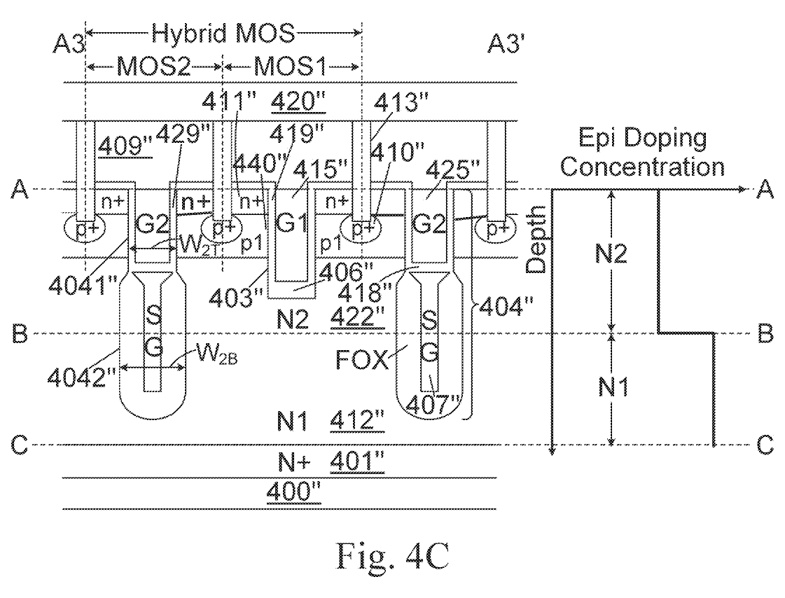

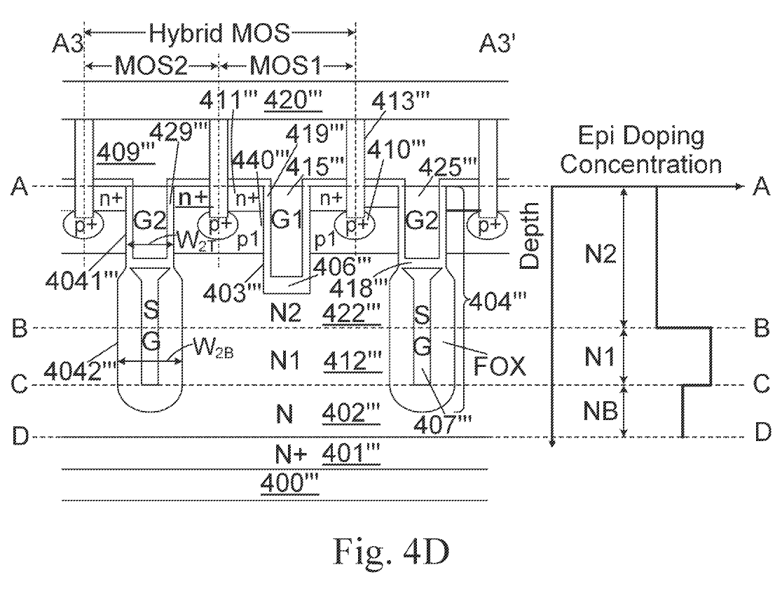

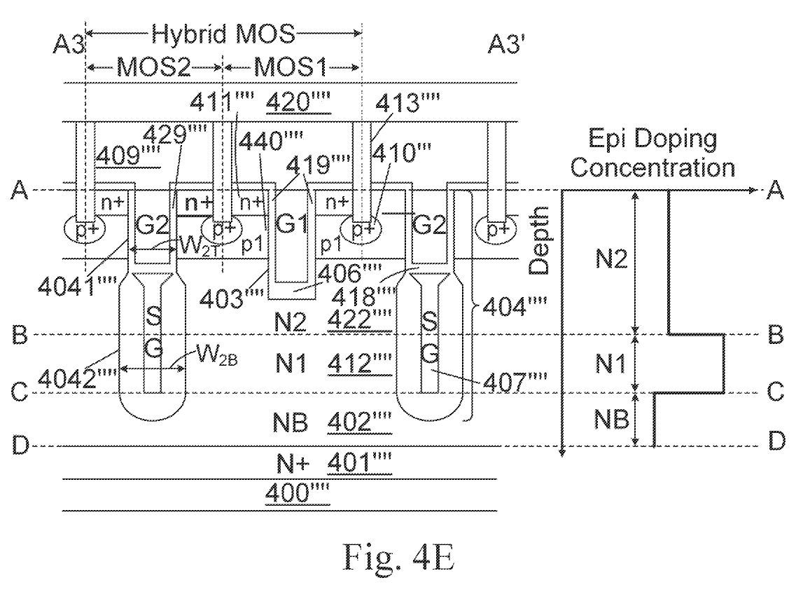

Please refer to FIG. 4A for a top view of another preferred embodiment for a trench semiconductor power device with stripe cells layout. The power device comprises a second MOSFET (MOS2, as illustrated) integrated with a first MOSFET (MOS1, as illustrated) to form a hybrid-channel MOSFET (HCMOSFET). In the present invention, a first gate electrode (G1, as illustrated) is formed in the first type gate trenches 403, and two electrodes including a second gate electrode (G2, as illustrated) and a shielded gate electrode (SG, as illustrated) are formed in the second type gate trenches 404, wherein G1 in the first type gate trenches 403 and G2 in the second type gate trenches 404 are shorted to a gate metal runner 435 through a first gate contact 415 and a second gate contact 425, and SG in the second type gate trenches 404 is shorted to a source metal 420 through a shielded gate contact trench 407. Moreover, the G2 is surrounded with a first gate oxide (GOX1, as illustrated) along sidewalls of an upper portion of the second type gate trenches 404, and the SG is surrounded with a first thick oxide (FOX, as illustrated) along sidewalls of a lower portion of the second type gate trenches 404, wherein GOX1 has a thickness thinner than that of FOX. Moreover, source contact trenches 413 are disposed between the adjacent first and second type gate trenches 403 and 404.

Please refer to FIG. 4B for a cross-sectional view showing a preferred embodiment along A3-A3’ line of FIG. 4A with a single epitaxial layer according to the present invention. The N-channel trenched semiconductor power device has a similar structure to FIG. 1B, except for the different gate trench structure in the second type gate trenches 404’. In the present invention, a second MOSFET (MOS2, as illustrated) is integrated with a first MOSFET (MOS1, as illustrated) to form a hybrid-channel MOSFET (HCMOSFET). A second type gate trench 404’ penetrates through a second body region 424’ and a second body region 421’ and stops in the N type epitaxial layer 402’, wherein said second body region 424’ has a doping concentration same as that of the first body region 414’. Inside each of the second type gate trenches 404’ of the MOS2, a second gate electrode (G2, as illustrated) 425’ is disposed in the second top gate trench 4041’ above the shielded gate electrode (SG, as illustrated) 407’ in the second bottom gate trench 4042’, and the G2 425’ is isolated with the SG 407’ by a second inter-polysilicon oxide (IPO2) layer 418’. Moreover, the G2 425’ is surrounded with a second gate oxide (GOX2) 429’ on sidewalls of the second top gate trench 4041’ with a thickness same as that of the GOX1 419’.

Please refer to FIG. 4C for a cross-sectional view showing another preferred embodiment along A3-A3’ line of FIG. 4A with a new and improved device structure having two stepped epitaxial layers wherein the doping concentration variations are depicted along the vertical direction according to the present invention. The N-channel trenched semiconductor power device has a similar structure to FIG. 4B, except that, the N type epitaxial layer in the present invention comprises two stepped epitaxial layers of different doping concentration including a bottom 1^{st} epitaxial layer (N1, as illustrated between B-B and C-C lines) 412’’ a with doping concentration D1 and a top 2^{nd} epitaxial layer (N2, as illustrated between A-A and B-B lines) 422’’ with a doping concentration D2, wherein D2< D1, to further reduce the specific on-resistance.

Please refer to FIG. 4D for a cross-sectional view showing another preferred embodiment along A3-A3’ line of FIG. 4A with a new and improved device structure having three stepped epitaxial layers wherein the doping concentration variations are depicted along the vertical direction according to the present invention. The N-channel trenched semiconductor power device has a similar structure to FIG. 4C, except that, the N type epitaxial layer in the present invention further comprises a buffer epitaxial layer (NB, as illustrated) 402’’’ between a bottom of the shielded gate electrode (SG, as illustrated) 407’’’ and the N+ substrate 401’’’ with a doping concentration DB, wherein D2<DB<D1.

Please refer to FIG. 4E for a cross-sectional view showing another preferred embodiment along A3-A3’ line of FIG. 4A with a new and improved device structure having three stepped epitaxial layers wherein the doping concentration variations are depicted along the vertical direction according to the present invention. The N-channel trenched semiconductor power device has a similar structure to FIG. 4C, except that, the N type epitaxial layer in the present invention further comprises a buffer epitaxial layer (NB, as illustrated) 402’’’’ between a bottom of the shielded gate electrode (SG, as illustrated) 407’’’’ and the N+ substrate 401’’’’ with a doping concentration DB, wherein DB<D2< D1.

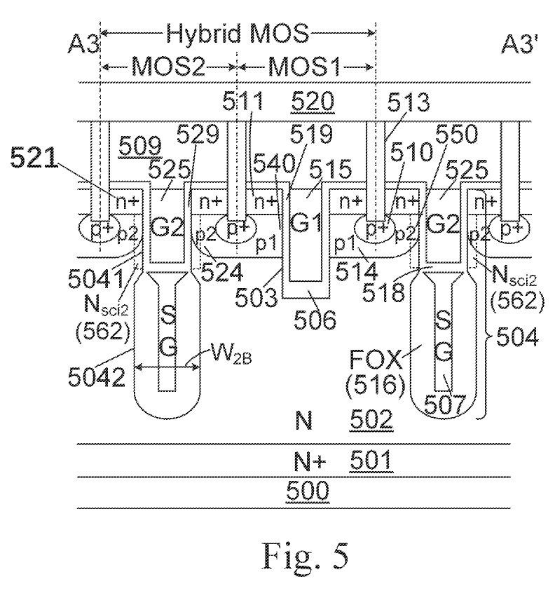

Please refer to FIG. 5 for a cross-sectional view showing another preferred embodiment along A3-A3’ line of FIG. 4A with a single epitaxial layer according to the present invention. The N-channel trenched semiconductor power device has a similar structure to FIG. 4B, except that the present invention in FIG. 5 further comprises a second p body (p2, as illustrated) region 524 of a second conductivity type having a second n+ source region 521 of a first conductivity type thereon, wherein the p2 body region 524 along sidewalls of the second top gate trench has a doping concentration lower than that of the p1 body region 514. A second channel region 550 of the second MOSFET (MOS2, as illustrated) region is thus formed in the p2 body region 524 along sidewalls of the second top gate trench 5041 connecting to the second n+ source region 521, while a first channel region 540 of the first MOSFET (MOS1, as illustrated) region is formed in the p1 body region 514 along sidewalls of the first type gate trench 503, and the second channel region 550 has a channel length shorter than that of the first channel region 540. Moreover, the present invention further comprises a second short channel implant region (Nsci2, as illustrated) 562 of a first conductivity type surrounding the second channel region 550 with a doping concentration higher than that of the N type epitaxial layer 502 to form two different threshold voltages of the hybrid-channel MOSFET comprising MOS1 and MOS2 with different threshold voltages to improve the positive temperature coefficient for reliability assurance operated at high temperatures, wherein a threshold voltage Vth2 of MOS2 is lower than a threshold voltage Vth1 of MOS1.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A power device having two types of gate trenches in each unit cell comprising:
an epitaxial layer of a first conductivity type grown on a substrate;
a first body region of a second conductivity type having a first source region of said first conductivity type thereon;
a first type gate trench penetrating said first body region and said first source region and stopping in said epitaxial layer;
a first gate electrode disposed in said first type gate trench and surrounded with a first gate oxide along sidewalls of said first type gate trench;
a first channel region of a first MOSFET formed in said first body region along sidewalls of said first type gate trench connecting to said first source region;
a second type gate trench formed in said epitaxial layer has one-step gate trench structure comprising a second top gate trench and a second bottom gate trench, wherein said second top gate trench is above said second bottom gate trench and has a trench width less than that of said second bottom gate trench; and said second type gate trench has a trench depth deeper than that of said first type gate trench; and
a first shielded gate electrode disposed in at least said second bottom gate trench surrounded with a first insulating film on a bottom region and along sidewalls of said second bottom gate trench; said first insulating film having a thickness greater than that of said first gate oxide;
said first body and said first source regions, and said shielded gate electrode being shorted to a source metal through source contact trenches and a shielded gate contact trench respectively.

2. The power device of claim 1, wherein said first shielded gate electrode has a wider width in a top portion of said second bottom gate trench than in other portions of said second bottom gate trench.

3. The power device of claim 1, wherein said first insulating film is formed by Local Oxidation of Silicon (LOCOS); sidewalls of said second top gate trench are padded with either a silicon nitride layer or two-layer stack of silicon nitride and silicon oxide during said LOCOS to prevent said sidewalls of said second top gate trench from oxidation.

4. The power device of claim 1, wherein said first shielded gate electrode disposed in said second top and second bottom gate trenches is surrounded with said first gated oxide along sidewalls of said second top gate trench.

5. The power device of claim 1, wherein said first shielded gate electrode disposed in said second top and second bottom gate trenches surrounded with a second gated oxide along sidewalls of said second top gate trench; said second gate oxide having a thickness less than that of said first gate oxide;
said power device further comprising a second body region of said second conductivity type having a second source region of said first conductivity type thereon; said second body region along said sidewalls of said second top gate trench has a doping concentration lower than that of said first body region;
said second type gate trench penetrating said second body region and said second source region and stopping in said epitaxial layer;
a second channel region of a super barrier rectifier (SBR) formed in said second body region along sidewalls of said second top gate trench connecting to said second source region; and
said SBR integrated with said first MOSFET in said each unit cell.

6. The power device of claim 5, further comprising a first short channel implant (SCI1) region of said first conductivity type surrounding said second channel region, wherein said SCI1 region is formed by a Arsenic or Phosphorus angle implantation along sidewalls of said second top gate trench of said second type gate trench, and having a doping concentration higher than that of said epitaxial layer; said second channel region has a channel length shorter than that of said first channel region.

7. The power device of claim 1, further comprising a second shielded gate electrode disposed below said first gate electrode and isolated from said first gate electrode with a second inter-polysilicon oxide layer (IPO1).

8. The power device of claim 1, further comprising a second gate electrode disposed in said second top gate trench above said shielded gate electrode in said second bottom gate trench, and isolated with said shielded gate electrode with a second inter-polysilicon oxide (IPO2) layer;
said second gate electrode surrounded with a second gate oxide on sidewalls of said second top gate trench; said second gate oxide has a thickness same as that of said first gate oxide;
a second body region of said second conductivity type having a second source region of said first conductivity type thereon;
said second type gate trench penetrating said second body region and said second source region and stopping in said epitaxial layer; and
a second channel region of a second MOSFET further formed in said second body region along said sidewalls of said second top gate trench connecting to said second source region; and
said second MOSFET forming a hybrid-channel MOSFET with said first MOSFET in said each unit cell.

9. The power device of claim 8, wherein said second body region has a doping concentration same as that of said first body region.

10. The power device of claim 8, further comprising a second short channel implant (SCI2) region of said first conductivity type surrounding said second channel region, wherein said SCI2 region having a doping concentration higher than that of said epitaxial layer; said second channel region has a channel length shorter than that of said first channel region; and said second body region along sidewalls of said second top gate trench has a doping concentration lower than that of said first body region.

11. The power device of claim 1, said first gate electrode surrounded with said first gate oxide on a bottom region of said first type gate trench.

12. The power device of claim 1, said first gate electrode surrounded with a second insulating film on a bottom region of said first type gate trench with a thickness greater than that of said first gate oxide.

13. The power device of claim 1, wherein said epitaxial layer is a single epitaxial layer with a uniform doping concentration.

14. The power device of claim 1, wherein said epitaxial comprises at least two stepped epitaxial layers of different doping concentrations including a bottom epitaxial layer with a doping concentration D1 and a top epitaxial layer above said bottom epitaxial layer with a doping concentration D2, wherein said D2< said D1.

15. The power device of claim 14, further comprising a buffer epitaxial layer between said substrate and said bottom epitaxial layers having a doping concentration DB, wherein said DB < said D 2< said D1

16. The power device of claim 14, further comprising a buffer epitaxial layer between said substrate and said bottom epitaxial layer having a doping concentration DB, wherein said D2 < said DB< said D1.

17. The power device of claim 1, further comprising an electric field reducing region of said first conductivity type surrounding said bottom region of said second type gate trench with a doping concentration lower than said epitaxial layer.

18. The power device of claim 1, wherein said first type and second gate trenches have a square, hexagonal or stripe shape.

19. The power device of claim 5, wherein said SBR has a square or a hexagonal shape, surrounded by said first MOSFET.

20. The Power device of claim 8, wherein said first type and second type gate trenches have a stripe shape.
